(19) United States
(12) Patent Application Publication
(10) Pub. No.: US 2025/0374534 A1
(43) Pub. Date: Dec. 4, 2025

(54) SEMICONDUCTOR MEMORY DEVICE

(71) Applicant: Samsung Electronics Co., Ltd., Suwon-si (KR)

(72) Inventors: Jeon Il LEE, Suwon-si (KR); Jinwoo HAN, Suwon-si (KR)

(73) Assignee: Samsung Electronics Co., Ltd., Suwon-si (KR)

(21) Appl. No.: 18/969,670

(22) Filed: Dec. 5, 2024

(30) Foreign Application Priority Data
May 28, 2024 (KR) 10-2024-0069444

(51) Int. Cl. H10B 12/00; G11C 5/06

(52) U.S. Cl. CPC H10B 12/50; G11C 5/063; H10B 12/482; H10B 12/488

(57) ABSTRACT

A semiconductor memory device includes a substrate including a cell region and a peripheral circuit region, a peripheral transistor on the peripheral circuit region and including a peripheral channel pattern, a plurality of cell channel patterns stacked on the cell region in a first direction, the first direction being perpendicular to an upper surface of the substrate, a word line on the plurality of cell channel patterns and the word line extending in a second direction, the second direction being perpendicular to the first direction, and a bit line connected to each of the plurality of cell channel patterns and the bit line extending in the first direction.

### CROSS-REFERENCE TO RELATED APPLICATION

This application claims priority to Korean Patent Application No. 10-2024-0069444, filed in the Korean Intellectual Property Office on May 28, 2024, the entire contents of which are hereby incorporated by reference.

### BACKGROUND

Example embodiments of the inventive concepts relate to a semiconductor memory device.

A semiconductor device may refer to a core component used to control or amplify an electrical signal in an electronic device, and various types of semiconductor devices may be manufactured. For example, memory devices may be used primarily to store and retrieve data, while non-memory devices may be used to control or amplify electrical signals. The semiconductor device is a core component of an electronic device and plays an important role in various fields including computers, communication equipment, consumer electronics, etc.

With the development of the semiconductor industry, the performance and function requirements of electronic devices are increasing. Accordingly, high-performance characteristics of semiconductor devices are required, and the degree of integration of semiconductor devices are increasing to meet these requirements. Accordingly, new transistor structures such as transistors with vertical channels and vertical stacks of transistors have been proposed.

### SUMMARY

According to some example embodiments of the inventive concepts, a semiconductor memory device includes a substrate including a cell region and a peripheral circuit region, a peripheral transistor on the peripheral circuit region and including a peripheral channel pattern, a plurality of cell channel patterns stacked on the cell region in a first direction, the first direction being perpendicular to an upper surface of the substrate, a word line on the plurality of cell channel patterns and the word line extending in a second direction, the second direction being perpendicular to the first direction, and a bit line connected to each of the plurality of cell channel patterns and the bit line extending in the first direction. A distance from the upper surface of the substrate to an upper surface of a cell channel pattern at an uppermost portion of the plurality of cell channel patterns is equal to or less than a distance from the upper surface of the substrate to an upper surface of the peripheral channel pattern.

According to some example embodiments of the inventive concepts, a semiconductor memory device includes a substrate including a cell region and a first peripheral circuit region, a first peripheral transistor on the first peripheral circuit region and including a peripheral channel pattern, a plurality of cell channel patterns stacked on the cell region in a first direction, the first direction being perpendicular to an upper surface of the substrate, a bit line connected to the plurality of cell channel patterns and the bit line extending in the first direction, an upper wiring structure spaced apart from each of the first peripheral transistor and the plurality of cell channel patterns in the first direction, a first contact via connected to the upper wiring structure and the bit line and extending in the first direction, and a second contact via connected to the upper wiring structure and the first peripheral transistor and extending in the first direction. A length of the first contact via in the first direction is greater than a length of the second contact via in the first direction.

According to some example embodiments of the inventive concepts, a semiconductor memory device includes a substrate including a cell region, a contact region, and a peripheral circuit region, a stack structure on the peripheral circuit region, a peripheral transistor on the stack structure and including a peripheral channel pattern, a plurality of cell channel patterns stacked on the cell region in a first direction, the first direction being perpendicular to an upper surface of the substrate, a word line on the plurality of cell channel patterns and the word line extending in a second direction, the second direction being perpendicular to the first direction, a bit line connected to one end of each of the plurality of cell channel patterns and the bit line extending in the first direction, and a plurality of capacitor structures respectively connected to an opposite end of each of the plurality of cell channel patterns. A distance from the upper surface of the substrate to an upper surface of a cell channel pattern at an uppermost portion of the plurality of cell channel patterns is less than a distance from the upper surface of the substrate to an upper surface of the peripheral channel pattern, and the word line has a stepped structure on the contact region.

### BRIEF DESCRIPTION OF THE DRAWINGS

The above example embodiments and features of the inventive concepts will become more apparent by describing in detail example embodiments thereof with reference to the attached drawings, in which:

FIG. 1 is an example circuit diagram illustrating a cell array of a semiconductor memory device according to some example embodiments;

FIG. 2 is a schematic diagram provided to explain a semiconductor memory device according to some example embodiments of the inventive concepts;

FIG. 3 is a plan view provided to explain a semiconductor memory device according to some example embodiments of the inventive concepts;

FIG. 4 is a cross-sectional view taken along lines A-A and B-B of FIG. 3;

FIG. 5 is a diagram provided to explain a semiconductor memory device according to some example embodiments of the inventive concepts;

FIG. 6 is a diagram provided to explain a semiconductor memory device according to some example embodiments of the inventive concepts;

FIG. 7 is a diagram provided to explain a semiconductor memory device according to some example embodiments of the inventive concepts;

FIG. 8 is a diagram provided to explain a semiconductor memory device according to some example embodiments of the inventive concepts;

FIG. 9 is a plan view provided to explain a semiconductor memory device according to some example embodiments of the inventive concepts;

FIG. 10 is a cross-sectional view taken along lines A-A and C-C of FIG. 9;

FIG. 11 is a diagram provided to explain a semiconductor memory device according to some example embodiments of the inventive concepts;

FIG. 12 is a diagram provided to explain a semiconductor memory device according to some example embodiments of the inventive concepts;

FIG. 13 is a plan view provided to explain a semiconductor memory device according to some example embodiments of the inventive concepts;

FIGS. 14 to 17 are diagrams showing an intermediate stage of process, which are provided to explain a method for manufacturing a semiconductor memory device according to some example embodiments of the inventive concepts;

FIGS. 18 to 20 are diagrams showing an intermediate stage of process, which are provided to explain a method for manufacturing a semiconductor memory device according to some example embodiments of the inventive concepts.

### DETAILED DESCRIPTION

Hereinafter, a semiconductor memory device and a method for manufacturing the same according to some example embodiments of the inventive concepts will be described in detail with reference to the drawings.

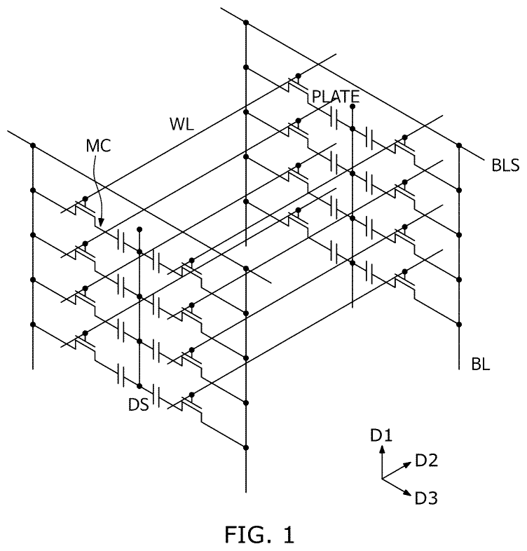

FIG. 1 is an example circuit diagram illustrating a cell array of a semiconductor memory device according to some example embodiments.

Referring to FIG. 1, the semiconductor memory device according to some example embodiments may include a plurality of memory cells MC arranged along a first direction D1 and a third direction D3. Each memory cell MC may include memory cell transistors and data storage devices DS arranged along the third direction D3 and connected to each other.

A plurality of bit lines BL may be conductive patterns (i.e., metallic conductive lines) extending in a vertical direction (i.e., in the first direction D1) from the substrate. The plurality of bit lines BL may be arranged in the third direction D3. Adjacent bit lines BL may be spaced apart from each other in the third direction D3.

In some example embodiments, some of the plurality of bit lines BL may be connected to each other by a bit line strapping line BLS. For example, the bit line bundle line BLS may connect the bit lines BL arranged along the third direction D3 of the plurality of bit lines BL to each other.

A plurality of word lines WL may be conductive patterns (i.e., metallic conductive lines) stacked on the substrate in the first direction D1. Each of the word lines WL may extend in a second direction D2. Adjacent word lines WL may be spaced apart from each other in the first direction D1.

The data storage devices DS may be commonly connected to plate electrodes PLATE extending in the first direction D1 and the second direction D2. In some example embodiments, the plate electrodes PLATE arranged along the second direction D2 may be integrally formed.

The data storage devices DS and the memory cell transistors arranged along the third direction D3 may be arranged symmetrically based on surfaces extending in the first direction D1 and the second direction D2 in which the plate electrodes PLATE are disposed.

Gates of the memory cell transistors may be connected to the word lines WL. A first source/drain of the memory cell transistor may be connected to the bit line BL. A second source/drain of the memory cell transistor may be connected to the data storage device DS. For example, the data storage device DS may be a capacitor structure. The second source/drain of the memory cell transistor may be connected to a storage electrode of the capacitor.

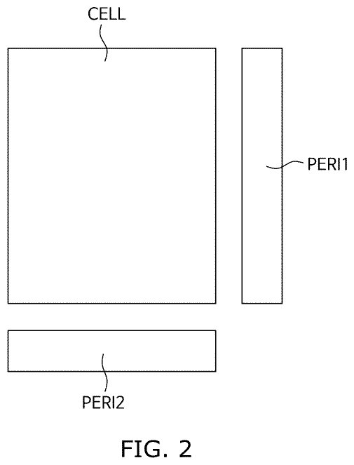

FIG. 2 is a schematic diagram provided to explain a semiconductor memory device according to some example embodiments of the inventive concepts.

The semiconductor device according to some example embodiments may include a cell region CELL and first and second peripheral circuit regions PERI1 and PERI2.

The cell region CELL may be a region in which a plurality of memory cells (i.e., the memory cells MC of FIG. 1) are disposed. The first and second peripheral circuit regions PERI1 and PERI2 may be disposed around the cell region CELL.

The first and second peripheral circuit regions PERI1 and PERI2 may be regions in which peripheral circuits are disposed. The peripheral circuits may play a role of transmitting signals and/or power to the plurality of memory cells. The peripheral circuits may form various circuits including a command decoder, a control logic, an address buffer, a row decoder, a column decoder, a sense amplifier, a sub word line driver, a data input and output circuit, although example embodiments are not limited thereto.

In some example embodiments, the sub word line driver may be disposed on the first peripheral circuit region PERI1, and the sense amplifier may be disposed on the second peripheral circuit region PERI2. However, example embodiments are not limited thereto. Elements disposed in the first peripheral circuit region PERI1 and the second peripheral circuit region PERI2 may vary depending on circuit designs.

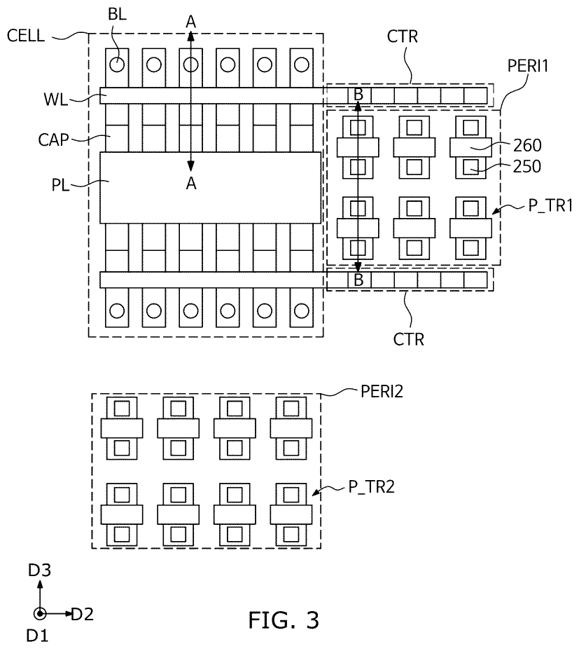

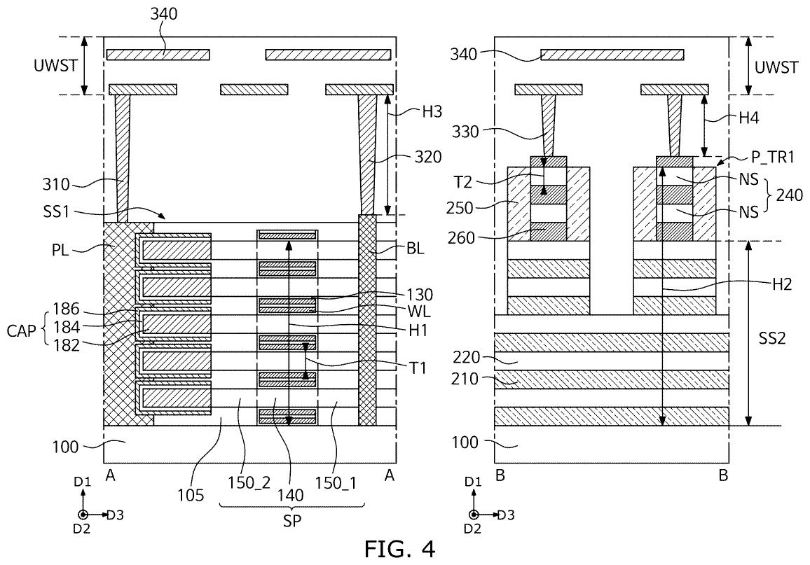

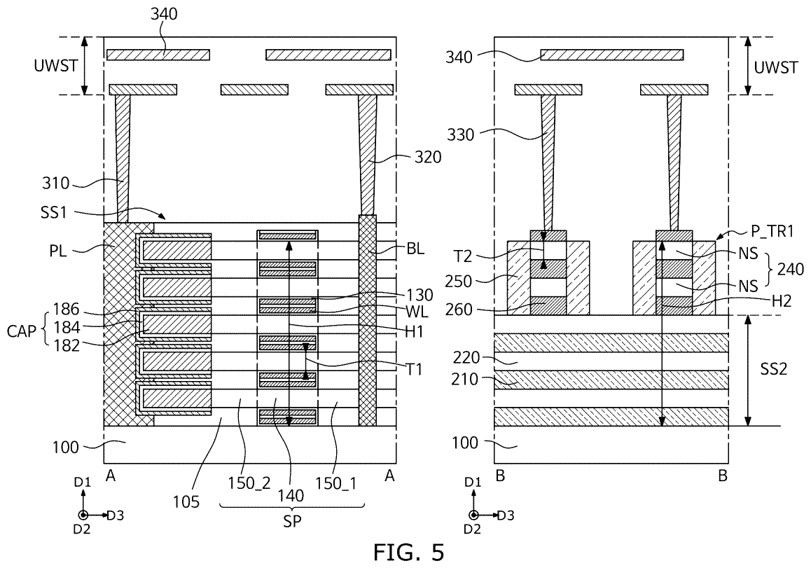

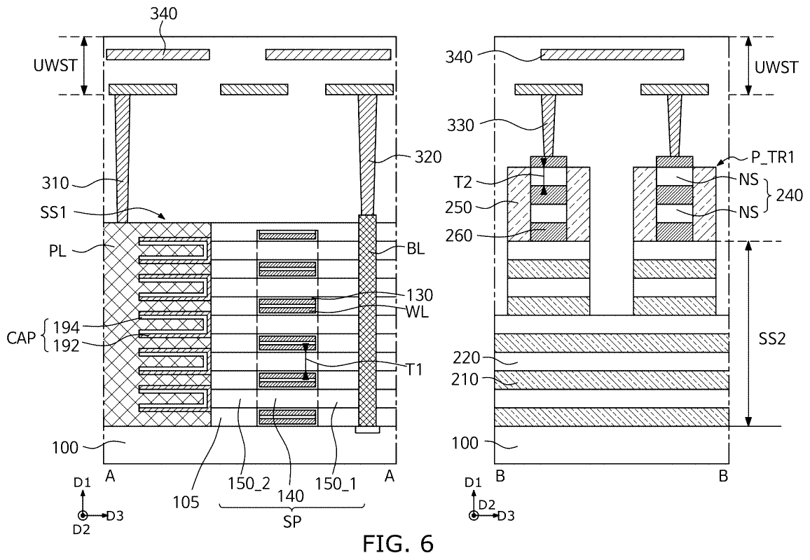

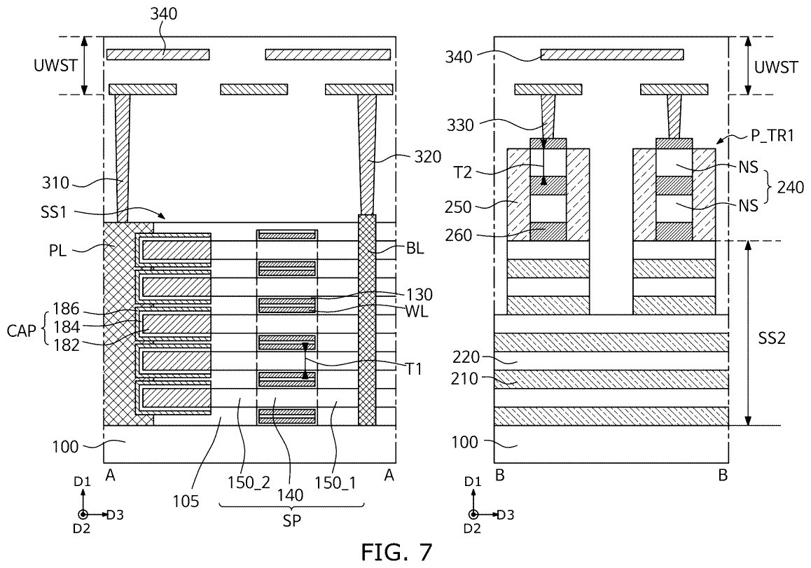

FIG. 3 is a plan view provided to explain a semiconductor memory device according to some example embodiments of the inventive concepts. FIG. 4 is a cross-sectional view taken along lines A-A and B-B of FIG. 3. FIG. 5 is a diagram provided to explain a semiconductor memory device according to some example embodiments of the inventive concepts. FIG. 6 is a diagram provided to explain a semiconductor memory device according to some example embodiments of the inventive concepts. FIG. 7 is a diagram provided to explain a semiconductor memory device according to some example embodiments of the inventive concepts. For reference, illustrations of an upper wiring structure UWST, first to third contact vias 310, 320 and 330, etc. are omitted in FIG. 3.

Referring to FIGS. 3 and 4, a substrate 100 including the cell region CELL, a contact region CTR, the first peripheral circuit region PERI1, and the second peripheral circuit region PERI2 may be provided.

The substrate 100 may be a bulk silicon or a silicon-on-insulator (SOI). The substrate 100 may include silicon (Si) or other materials such as, for example, silicon-germanium on insulator (SGOI), indium antimony (InSb), lead tellurite compound (PbTe), indium arsenic (InAs), indium phosphide (INP), gallium arsenic (GaAs), gallium antimony (GaSb), etc., although aspects are not limited thereto. However, example embodiments are not limited thereto. Hereinafter, for convenience of explanation, it will be assumed that the substrate 100 is a substrate including silicon.

A first stack structure SS1 may be disposed on the cell region CELL of the substrate 100.

The first stack structure SS1 may include a plurality of cell insulating films 105 and a plurality of cell semiconductor patterns SP which are alternately stacked on each other. A plurality of cell insulating films 105 and a plurality of cell semiconductor patterns SP may be alternately and repeatedly stacked on each other in the first direction D1. The first direction D1 may be a direction perpendicular to an upper surface of the substrate 100. The second direction D2 and the third direction D3 may be directions parallel to the upper surface of the substrate 100. The second direction D2 may be perpendicular to the third direction D3.

The cell semiconductor pattern SP may have a line shape, a bar shape, or a pillar shape extending in the third direction D3. The cell semiconductor patterns SP may pass through the word lines WL.

For example, the cell semiconductor pattern SP may include silicon, germanium, silicon-germanium, indium gallium zinc oxide (IGZO) or indium tin zinc oxide (ITZO). However, example embodiments are not limited thereto. In addition, for example, the cell semiconductor pattern SP may include a two-dimensional semiconductor material.

The cell semiconductor pattern SP may include a cell channel pattern 140, a first source/drain pattern 150_1, and a second source/drain pattern 150_2.

The cell channel pattern 140 may be disposed between the first source/drain pattern 150_1 and the second source/drain pattern 150_2. The cell channel pattern 140 may be disposed between the word lines WL. In some example embodiments, the word line WL may have a structure (i.e., a gate all around structure) that completely surrounds the cell channel pattern 140.

The first source/drain pattern 150_1 may be disposed at one end of the cell channel pattern 140. The first source/drain pattern 150_1 may be connected to the bit line BL. The second source/drain pattern 150_2 may be disposed at the other end of the cell channel pattern 140. The second source/drain pattern 150_2 may be connected to a capacitor structure CAP.

The first source/drain pattern 150_1 and the second source/drain pattern 150_2 may have a first conductivity type (i.e., an n-type). The cell channel pattern 140 may be undoped or may have a second conductivity type (i.e., a p-type) different from the first conductivity type. However, example embodiments are not limited thereto.

Each of the plurality of word lines WL may extend in the second direction D2 parallel to the upper surface of the substrate 100. Each of the plurality of word lines WL may surround the cell channel pattern 140. The plurality of word lines WL may be disposed in the contact region CTR. The plurality of word lines WL may have a step shape on the contact region CTR. Each of the plurality of word lines WL may include a pad portion whose upper surface is partially exposed due to the step shape. A word line contact may be disposed on the pad portion of the word line WL.

The word line WL may include a conductive material. For example, the word line WL may include at least one of doped semiconductor material (doped silicon, doped silicon-germanium, doped germanium, etc.), conductive metal nitride (titanium nitride, tantalum, etc.), metal (tungsten, titanium, tantalum, etc.), and metal-semiconductor compound (tungsten silicide, cobalt silicide, titanium silicide, etc.), but example embodiments are not limited thereto.

A gate insulating film 130 may be disposed between the cell channel pattern 140 and the word line WL. The gate insulating films 130 may surround the cell channel pattern 140. The word line WL may be disposed on the gate insulating film 130. The gate insulating film 130 may include at least one of a high-k insulating film, a silicon oxide film, a silicon nitride film, and a silicon oxynitride film. For example, the high-k insulating film may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobium salt. However, example embodiments are not limited thereto.

The cell insulating film 105 may be disposed between the cell semiconductor patterns SP stacked in the first direction D1. A portion of the cell insulating film 105 may be disposed between adjacent word lines WL in the first direction D1. The cell insulating film 105 may electrically separate the word lines WL. The other portion of the cell insulating film 105 may be disposed between adjacent capacitor structures CAP in the first direction D1.

The cell insulating film 105 may include an insulating material. For example, the cell insulating film 105 may be selected from the group consisting of a silicon oxide film, a silicon nitride film, a silicon oxynitride film, a carbon-containing silicon oxide film, a carbon-containing silicon nitride film, and a carbon-containing silicon oxynitride film. However, example embodiments are not limited thereto.

As illustrated in FIG. 4, the capacitor structure CAP may include a first electrode 182, a first dielectric film 184, and a second electrode 186. The first electrode 182 may be disposed at one end of the cell semiconductor pattern SP. The first electrode 182 may be connected to the second source/drain pattern 150_2. The first electrode 182 may have a pillar shape extending in the third direction D3.

The first electrode 182 may include at least one of a metal material, a metal nitride film, and a metal silicide. For example, the first electrode 182 may include a high-melting point metal film such as cobalt, titanium, nickel, tungsten, molybdenum, etc. However, example embodiments are not limited thereto. In addition, for example, the first electrode 182 may include a metal nitride film such as a titanium nitride film, a titanium silicon nitride film, a titanium aluminum nitride film, a tantalum silicon nitride film, a tantalum aluminum nitride film, a tungsten nitride film, etc. However, example embodiments are not limited thereto.

The first dielectric film 184 may be disposed between the first electrode 182 and the second electrode 186. The first dielectric film 184 may be disposed along a profile of the first electrode 182. For example, the first dielectric film 184 may include at least one of a metal oxide such as hafnium oxide, zirconium oxide, aluminum oxide, lanthanum oxide, tantalum oxide, titanium oxide, etc., or a dielectric material having a perovskite structure such as SrTiO₃ (STO), (Ba, Sr)TiO₃(BST), BaTiO₃, PZT, PLZT, etc. However, example embodiments are not limited thereto.

The second electrode 186 may be disposed on the first dielectric film 184. The second electrode 186 may extend along the first dielectric film 184. The second electrode 186 may be connected to a plate electrode PL. For example, the second electrode 186 may include at least one of silicon doped with impurities, a metal material, a metal nitride film, or a metal silicide. In some example embodiments, the second electrode 186 may include substantially the same material as the first electrode 182.

The plate electrode PL may extend in the first direction D1 and the second direction D2. The plate electrode PL may be in contact with the second electrode 186. The plate electrode PL may be electrically connected to a plurality of second electrodes 186 disposed in the first direction D1. The plate electrode PL may include a conductive material. For example, the plate electrode PL may include any one of a doped semiconductor material, a conductive metal nitride, a metal, and a metal-semiconductor compound. However, example embodiments are not limited thereto. The plate electrode PL may be the plate electrode PLATE described above with reference to FIG. 1.

Referring to FIG. 6, the capacitor structure CAP may include a third electrode 192 and a second dielectric film 194. The third electrode 192 may be disposed at one end of the cell semiconductor pattern SP. The third electrode 192 may be connected to the second source/drain pattern 150_2. The third electrode 192 may have a hollow cylinder shape. The plate electrode PL may fill a cylindrical inner space of the third electrode 192. In addition, the plate electrode PL may be disposed outside the third electrode 192. The second dielectric film 194 may be disposed between the third electrode 192 and the plate electrode PL.

The description of the material of the third electrode 192 may be the same as that of the first electrode 182 of FIG. 4, and the description of the material of the second dielectric film 194 may be the same as that of the first dielectric film 184 of FIG. 4.

Referring back to FIGS. 3 and 4, a plurality of bit lines BL may be disposed on the substrate 100. The plurality of bit lines BL may be spaced apart and aligned in the second direction D2. The bit lines BL may extend in the first direction D1. The bit lines BL may pass through the first stack structure SS1. For example, the bit lines BL may pass through a plurality of stacked cell semiconductor patterns SP. The cell semiconductor patterns SP may be connected to the bit lines BL. For example, the bit lines BL may be electrically connected to the first source/drain pattern 150_1 of the cell semiconductor pattern SP.

The first peripheral circuit region PERI1 may be disposed around the cell region CELL. In some example embodiments, the first peripheral circuit region PERI1 may be disposed between the contact regions CTR. However, example embodiments are not limited thereto.

A second stack structure SS2 may be provided on the first peripheral circuit region PERI1 of the substrate 100. The second stack structure SS2 may be disposed on the upper surface of the substrate 100. The second stack structure SS2 may include a plurality of first semiconductor layers 210 and a plurality of second semiconductor layers 220 which are alternately stacked on each other. The plurality of first semiconductor layers 210 and the plurality of second semiconductor layers 220 may be alternately and repeatedly stacked in the first direction D1.

In some example embodiments, the second semiconductor layer 220 of the second stack structure SS2 may be disposed on the same level with the cell channel pattern 140. Specifically, based on the upper surface of the substrate 100, a height to an upper surface of the cell channel pattern 140 may be equal to a height to the upper surface of the second semiconductor layer 220. In other words, the cell channel pattern 140 may overlap the second semiconductor layer 220 in the third direction D3.

For example, the first semiconductor layer 210 may include silicon germanium (SiGe). For example, the second semiconductor layer 220 may include silicon (Si). However, example embodiments are not limited thereto. In some example embodiments, the first semiconductor layer 210 may include silicon germanium (SiGe) and impurities. For example, the impurities may include carbon (C), boron (B), etc. However, example embodiments are not limited thereto.

In some example embodiments, a trench may be formed on an upper portion of the second stack structure SS2. The trench may be disposed between first peripheral circuit transistors P_TR1. A field insulating film may be disposed on the trench. The field insulating film may separate the first peripheral circuit transistors P_TR1.

The first peripheral circuit transistor P_TR1 may be disposed on the second stack structure SS2. For example, the first peripheral transistor P_TR1 may be disposed on the upper surface of the second stack structure SS2. The first peripheral circuit transistor P_TR1 may be electrically connected to the first stack structure SS1 of the cell region CELL. For example, the first peripheral circuit transistor P_TR1 may be electrically connected to the word line WL. However, example embodiments are not limited thereto. For example, the first peripheral circuit transistor P_TR1 may be electrically connected to the bit line BL.

The first peripheral transistor P_TR1 may include a peripheral channel pattern 240, a peripheral gate electrode 260, and a peripheral source/drain pattern 250.

The peripheral channel pattern 240 may be a channel region of the first peripheral transistor P_TR1. For example, the first peripheral transistor P_TR1 may be a multi bridge channel FET (MBCFET). However, example embodiments are not limited thereto. Unlike the illustration, the first peripheral transistor P_TR1 may be a planar transistor (i.e., a planar FET) rather than the 3D transistor (i.e., MBCFET).

In some example embodiments, the peripheral channel pattern 240 may include a plurality of sheet patterns NS. Although it is illustrated that there are two sheet patterns NS, example embodiments are not limited thereto. The number of sheet patterns NS may be one or three or more.

For example, the sheet pattern NS may include one of element semiconductor material such as silicon (Si) or silicon germanium (SiGe), a group IV-IV compound semiconductor, or a group III-V compound semiconductor. However, example embodiments are not limited thereto. In some example embodiments, the sheet pattern NS may include the same material as the cell channel pattern 140.

The peripheral gate electrode 260 may surround the peripheral channel pattern 240. For example, the peripheral gate electrode 260 may surround the plurality of sheet patterns NS. Although not illustrated, a peripheral gate insulating film may be disposed between the peripheral gate electrode 260 and the plurality of sheet patterns NS. The peripheral gate insulating film may include a high-k insulating film and/or an interfacial insulating film.

The peripheral gate electrode 260 may include at least one of a metal, a metal alloy, a conductive metal nitride, a metal silicide, a doped semiconductor material, a conductive metal oxide, or a conductive metal oxynitride. However, example embodiments are not limited thereto.

The peripheral source/drain patterns 250 may be arranged on both sides of the peripheral channel pattern 240. The peripheral source/drain pattern 250 may be the source/drain of the first peripheral transistor P_TR1. For example, the peripheral source/drain pattern 250 may include silicon (Si), silicon-germanium (SiGe), germanium (Ge), silicon carbide (SiC), etc., but example embodiments are not limited thereto.

The upper surface of the peripheral channel pattern 240 may be disposed to be equal to or higher than the upper surface of the cell channel pattern 140 disposed at the uppermost portion of the plurality of cell channel patterns 140. Specifically, a distance from the upper surface of the substrate 100 to the upper surface of the cell channel pattern 140 disposed at the uppermost portion of the plurality of cell channel patterns 140 may be a first height H1. A distance from the upper surface of the substrate 100 to the upper surface of the peripheral channel pattern 240 may be a second height H2. The upper surface of the peripheral channel pattern 240 may refer to an upper surface of the sheet pattern NS disposed at the uppermost portion of the plurality of sheet patterns NS. As illustrated in FIG. 4, the first height H1 may be less than the second height H2, and as illustrated in FIG. 5, the first height H1 may be equal to the second height H2.

In some example embodiments, as illustrated in FIGS. 4 and 5, each of the plurality of cell channel patterns 140 may have the same thickness. The cell channel pattern 140 may have a first thickness T1. The peripheral channel pattern 240 may have a second thickness T2. For example, the sheet pattern NS of the peripheral channel pattern 240 may have the second thickness T2. Each of the first thickness T1 and the second thickness T2 may refer to a thickness in the first direction D1. The first thickness T1 may be the same as the second thickness T2.

Referring to FIG. 7, the first thickness T1 may be different from the second thickness T2. For example, the second thickness T2 may be greater than the first thickness T1. However, example embodiments are not limited thereto. Unlike the illustration, the second thickness T2 may be less than the first thickness T1.

Referring again to FIGS. 3 and 4, the upper wiring structure UWST may be disposed on the first stack structure SS1 and the first peripheral transistor P_TR1. The upper wiring structure UWST may be disposed to be spaced apart from each of the plurality of cell channel patterns 140 and the first peripheral transistor P_TR1 in the first direction D1. The upper wiring structure UWST may include a conductive pattern 340. The upper wiring structure UWST may be a wiring that electrically connects the cell region CELL and the first and second peripheral circuit regions PERI1 and PERI2.

A first contact via 310 may be disposed between the upper wiring structure UWST and the plate electrode PL. The first contact via 310 may electrically connect the upper wiring structure UWST and the plate electrode PL. The first contact via 310 may extend in the first direction D1.

The second contact via 320 may be disposed between the upper wiring structure UWST and the bit line BL. The second contact via 320 may electrically connect the upper wiring structure UWST and the bit line BL. The second contact via 320 may extend in the first direction D1. The second contact via 320 may have a third height H3 in the first direction D1.

The third contact via 330 may be disposed between the upper wiring structure UWST and the first peripheral transistor P_TR1. The third contact via 330 may electrically connect the upper wiring structure UWST and the first peripheral transistor P_TR1. The third contact via 330 may extend in the first direction D1. The third contact via 330 may have a fourth height H4 in the first direction D1. The fourth height H4 may be less than the third height H3.

As the fourth height H4 decreases, a current path between the first peripheral transistor P_TR1 and the upper wiring structure UWST may be shortened. Accordingly, a margin required to sense an electrical characteristic of a device connected to the first peripheral transistor P_TR1 may increase. That is, the electrical characteristics and/or reliability of the semiconductor memory device may be improved. In addition, the difficulty of the process of forming the third contact via 330 may be reduced.

The second peripheral circuit region PERI2 may be disposed around the cell region CELL. A second peripheral transistor P_TR2 may be disposed on the second peripheral circuit region PERI2. The description of the second peripheral transistor P_TR2 may be substantially the same as that of the first peripheral transistor P_TR1. As described with respect to the first peripheral transistor P_TR1, a current path between the second peripheral transistor P_TR2 and the upper wiring structure UWST may be shortened. Accordingly, electrical characteristics of the semiconductor memory device can be improved. For example, when the second peripheral transistor P_TR2 and the bit line BL are electrically connected, the sensing margin of the bit line BL may be improved.

Although the second peripheral transistor P_TR2 has been described as being electrically connected to the bit line BL, example embodiments are not limited thereto. For example, the first peripheral transistor P_TR1 may be electrically connected to the bit line BL, and the second peripheral transistor P_TR2 may be electrically connected to the word line WL. As another example, the first peripheral transistor P_TR1 and the second peripheral transistor P_TR2 may be designed to be electrically connected to other devices disposed outside the cell region CELL.

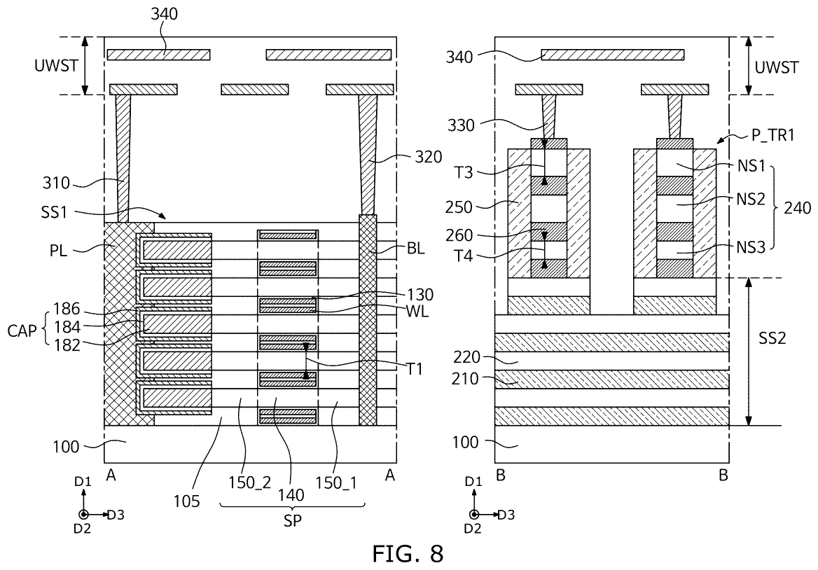

FIG. 8 is a diagram provided to explain a semiconductor memory device according to some example embodiments of the inventive concepts. For reference, FIG. 8 may correspond to cross-sectional views taken along lines A-A and B-B of FIG. 3. For convenience of description, different configurations from those described in FIGS. 3 and 4 will be mainly described.

Referring to FIG. 8, the first peripheral transistor P_TR1 may include the peripheral channel pattern 240, the peripheral gate electrode 260, and the peripheral source/drain pattern 250.

The peripheral channel pattern 240 may be a channel region of the first peripheral transistor P_TR1. The peripheral channel pattern 240 may include first to third sheet patterns NS1, NS2, and NS3. Each of the first to third sheet patterns NS1, NS2, and NS3 may be disposed to be spaced apart in the first direction D1. The first sheet pattern NS1 may be disposed on the second sheet pattern NS2. The second sheet pattern NS2 may be disposed on the third sheet pattern NS3. The second sheet pattern NS2 may be disposed between the first sheet pattern NS1 and the third sheet pattern NS3.

In some example embodiments, the thickness of each of the first to third sheet patterns NS1, NS2, and NS3 may not be constant in the first direction D1. Specifically, the first sheet pattern NS1 may have a third thickness T3. The thickness of the second sheet pattern NS2 may be the same as the third thickness T3 of the first sheet pattern NS1. The third sheet pattern NS3 may have a fourth thickness T4 less than the third thickness T3.

In the first direction D1, the cell channel pattern 140 may have the first thickness T1. The third thickness T3 may be greater than the first thickness T1. The fourth thickness T4 may be the same as the first thickness T1.

In some example embodiments, the third sheet pattern NS3 may be disposed on the same level with any one cell channel pattern 140 of the plurality of cell channel patterns 140. In other words, the third sheet pattern NS3 may overlap any one cell channel pattern 140 of the plurality of cell channel patterns 140 in the third direction D3.

In FIG. 8, the peripheral channel pattern 240 is described as including three sheet patterns NS1, NS2, and NS3, but example embodiments are not limited thereto.

The peripheral gate electrode 260 may surround the peripheral channel pattern 240. For example, the peripheral gate electrode 260 may surround the first to third sheet patterns NS1, NS2, and NS3. The peripheral source/drain patterns 250 may be disposed on both sides of the peripheral channel pattern 240. The peripheral source/drain pattern 250 may be the source/drain of the first peripheral transistor P_TR1.

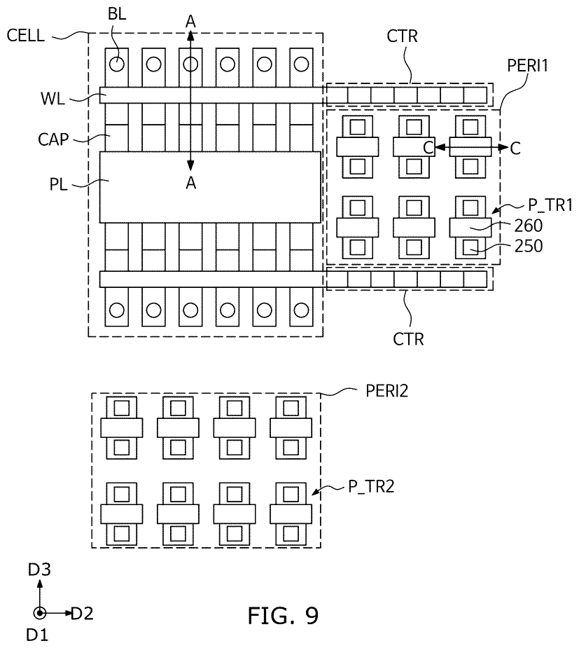

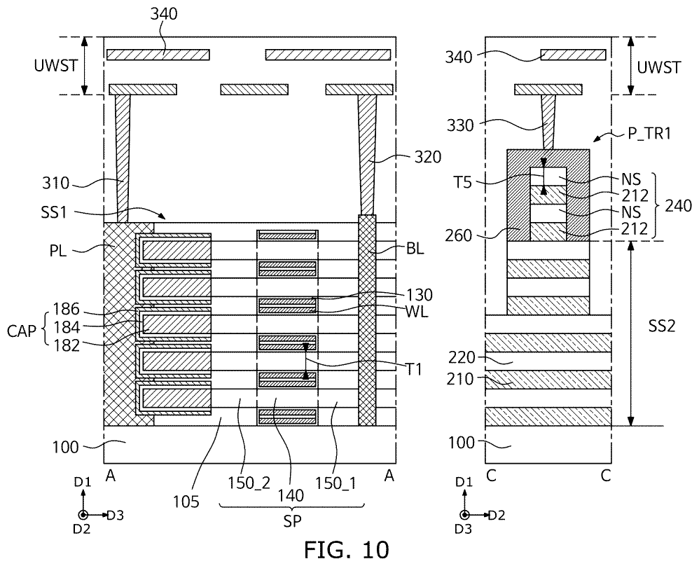

FIG. 9 is a plan view provided to explain a semiconductor memory device according to some example embodiments of the inventive concepts. FIG. 10 is a cross-sectional view taken along lines A-A and C-C of FIG. 9. For reference, illustrations of the upper wiring structure UWST, the first to third contact vias 310, 320 and 330, etc. are omitted in FIG. 9. For convenience of description, different configurations from those described in FIGS. 3 and 4 will be mainly described.

Referring to FIGS. 9 and 10, the second stack structure SS2 may be provided on the first peripheral circuit region PERI1 of the substrate 100. The first peripheral circuit transistor P_TR1 may be disposed on the second stack structure SS2. The second stack structure SS2 may include the plurality of first semiconductor layers 210 and the plurality of second semiconductor layers 220 which are alternately stacked on each other.

The first peripheral transistor P_TR1 may include the peripheral channel pattern 240, the peripheral gate electrode 260, and the peripheral source/drain pattern. The peripheral channel pattern 240 may be a channel region of the first peripheral transistor P_TR1. The peripheral channel pattern 240 may have a fin shape. The peripheral channel pattern 240 may extend in the third direction D3. The peripheral gate electrode 260 may surround at least three surfaces of the peripheral channel pattern 240. The peripheral source/drain patterns may be disposed on both sides of the peripheral channel pattern 240. For example, the first peripheral transistor P_TR1 may be FinFET.

In some example embodiments, the peripheral channel pattern 240 may include a plurality of layers. For example, the peripheral channel pattern 240 may include the plurality of channel semiconductor layers 212 and the plurality of sheet patterns NS which are alternately stacked on each other. The sheet pattern NS may have a fifth thickness T5. The fifth thickness T5 may refer to a thickness in the first direction D1. The fifth thickness T5 may be the same as the first thickness T1. However, example embodiments are not limited thereto. The fifth thickness TR may be greater or less than the first thickness T1.

For example, the sheet pattern NS may include one of element semiconductor material such as silicon (Si) or silicon germanium (SiGe), a group IV-IV compound semiconductor, or a group III-V compound semiconductor. However, example embodiments are not limited thereto.

In some example embodiments, the first semiconductor layer 210 and the channel semiconductor layer 212 may include the same material, and the second semiconductor layer 220 and the sheet pattern NS may include the same material. However, example embodiments are not limited thereto. For example, the first semiconductor layer 210 and the channel semiconductor layer 212 may include different materials, and the second semiconductor layer 220 and the sheet pattern NS may include different materials.

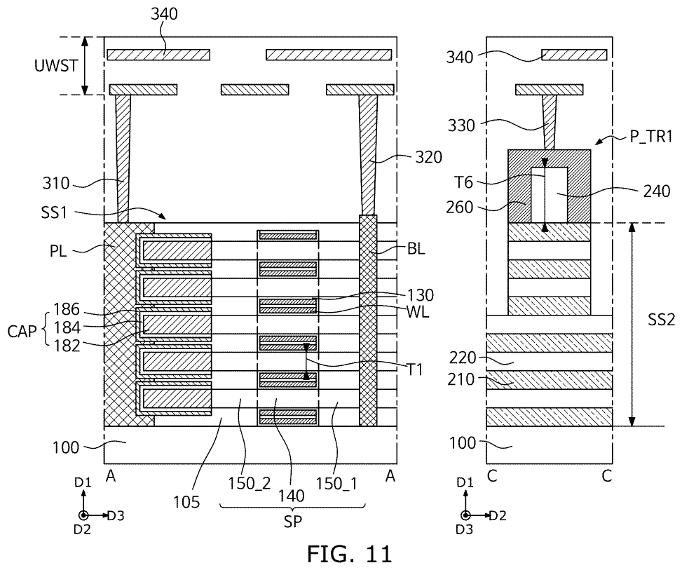

FIG. 11 is a diagram provided to explain a semiconductor memory device according to some example embodiments of the inventive concepts. For reference, FIG. 11 may correspond to cross-sectional views taken along lines A-A and C-C of FIG. 9. For convenience of description, different configurations from those described in FIGS. 3 and 4 will be mainly described.

Referring to FIGS. 9 and 11, the second stack structure SS2 may be provided on the first peripheral circuit region PERI1 of the substrate 100. The first peripheral circuit transistor P_TR1 may be disposed on the second stack structure SS2. The second stack structure SS2 may include the plurality of first semiconductor layers 210 and the plurality of second semiconductor layers 220 which are alternately stacked on each other.

The first peripheral transistor P_TR1 may include the peripheral channel pattern 240, the peripheral gate electrode 260, and the peripheral source/drain pattern. The peripheral channel pattern 240 may be a channel region of the first peripheral transistor P_TR1. The peripheral channel pattern 240 may have a fin shape. The peripheral channel pattern 240 may extend in the third direction D3. The peripheral gate electrode 260 may surround at least three surfaces of the peripheral channel pattern 240. The peripheral source/drain patterns may be disposed on both sides of the peripheral channel pattern 240. For example, the first peripheral transistor P_TR1 may be FinFET.

The peripheral channel pattern 240 may be formed as a single layer. The peripheral channel pattern 240 may have a sixth thickness T6. The sixth thickness T6 may be a thickness in the first direction D1. The sixth thickness T6 may be greater than the first thickness T1.

Although the upper surface of the first stack structure SS1 and the upper surface of the second stack structure SS2 are illustrated to be disposed on the same level, it should be understood that this is example. For example, the upper surface of the first stack structure SS1 and the upper surface of the second stack structure SS2 may be disposed on different levels.

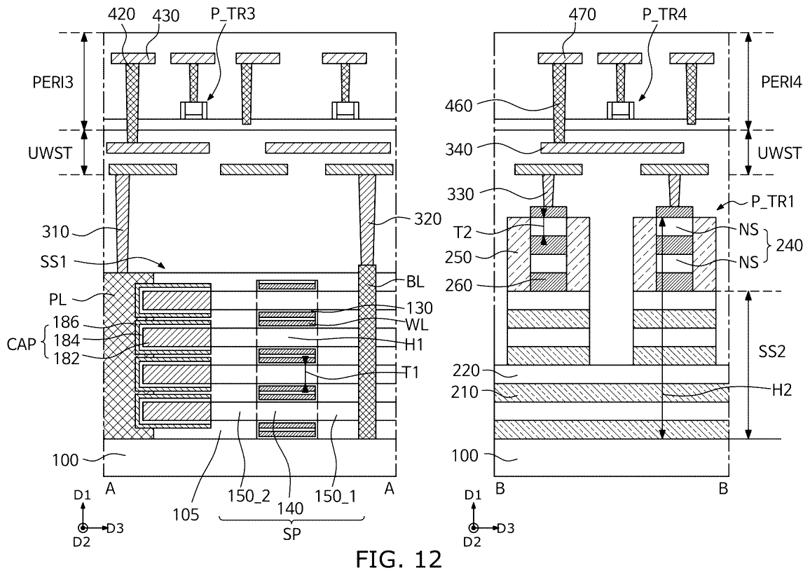

FIG. 12 is a diagram provided to explain a semiconductor memory device according to some example embodiments of the inventive concepts. For convenience of description, different configurations from those described in FIGS. 3 and 4 will be mainly described.

Referring to FIGS. 3 and 12, a third peripheral circuit region PERI3 and a fourth peripheral circuit region PERI4 may be disposed on the upper wiring structure UWST.

The third peripheral circuit region PERI3 may be disposed on an upper surface of the upper wiring structure UWST. The third peripheral circuit region PERI3 may overlap the cell region CELL in the first direction D1.

The third peripheral circuit region PERI3 may include a third peripheral transistor P_TR3, a first through via 420, and a first upper conductive pattern 430. The first through via 420 may electrically connect the first upper conductive pattern 430 and the upper wiring structure UWST. The third peripheral transistor P_TR3 may be electrically connected to the first stack structure SS1 through the first upper conductive pattern 430 and the first through via 420. Additionally or alternatively, the third peripheral transistor P_TR3 may be electrically connected to at least one of the first peripheral transistor P_TR1, the second peripheral transistor P_TR2, and a fourth peripheral transistor P_TR4 through the first upper conductive pattern 430 and the first through via 420.

The fourth peripheral circuit region PERI4 may be disposed on the upper surface of the upper wiring structure UWST. The fourth peripheral circuit region PERI4 may be disposed on the same level with the third peripheral circuit region PERI3. The fourth peripheral circuit region PERI4 may overlap the first peripheral circuit region PERI1 in the first direction D1.

The fourth peripheral circuit region PERI4 may include the fourth peripheral transistor P_TR4, a second through via 460, and a second upper conductive pattern 470. The second through via 460 may electrically connect the second upper conductive pattern 470 and the upper wiring structure UWST. The fourth peripheral transistor P_TR4 may be electrically connected to the first stack structure SS1 through the second upper conductive pattern 470 and the second through via 460. Additionally or alternatively, the fourth peripheral transistor P_TR4 may be electrically connected to at least one of the first peripheral transistor P_TR1, the second peripheral transistor P_TR2, and the third peripheral transistor P_TR3 through the second upper conductive pattern 470 and the second through via 460.

In some example embodiments, the third peripheral circuit region PERI3 may be a region in which a sub word line driver circuit is disposed. For example, the third peripheral transistor P_TR3 may be electrically connected to the word line WL disposed in the CELL region. In addition, the first peripheral transistor P_TR1 may be electrically connected to the bit line BL. Accordingly, a current path connecting the first peripheral transistor P_TR1 and the bit line BL may be reduced, thereby improving sensing margin. In addition, the third peripheral circuit region PERI3 may be disposed to overlap the cell region CELL in the first direction D1, thereby improving the integration of the semiconductor memory device. Therefore, electrical characteristics and/or reliability of the semiconductor device may be improved.

In some example embodiments, the semiconductor memory device may include a structure of a processing in memory (PIM) block. For example, the command decoder, the control logic, the address buffer, the row decoder, the column decoder, the sense amplifier, the sub word line driver, the data input and output circuit, etc., may be disposed on the first peripheral circuit region PERI1 and the third peripheral circuit region PERI3. A PIM block including an arithmetic logic circuit, a register, and a controller may be disposed on the fourth peripheral circuit region PERI4. For example, the arithmetic logic circuit may include a Neural Processing Unit (NPU), a Graphics Processing Unit (GPU), etc., but example embodiments are not limited thereto.

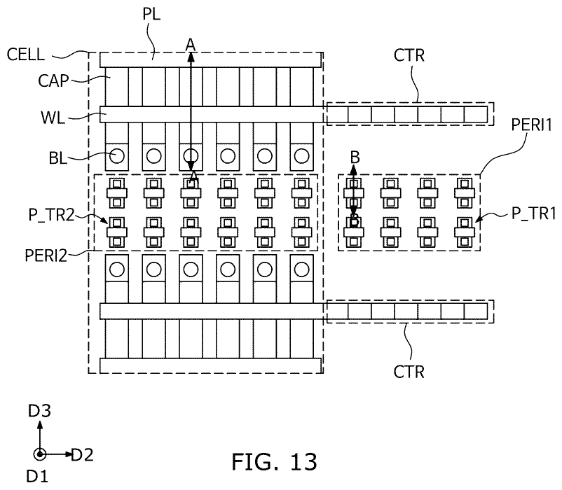

FIG. 13 is a plan view provided to explain a semiconductor memory device according to some example embodiments of the inventive concepts. For convenience of description, different configurations from those described in FIGS. 3 to 11 will be mainly described.

Referring to FIG. 13, the semiconductor memory device according to some example embodiments may include the cell region CELL, the first peripheral circuit region PERI1, and the second peripheral circuit region PERI2.

The cell region CELL may be a region in which a plurality of memory cells (i.e., the memory cells MC of FIG. 1) are disposed. The first and second peripheral circuit regions PERI1 and PERI2 may be regions in which peripheral circuits are disposed. The peripheral circuits may play a role of transmitting signals and/or power to the plurality of memory cells. The first peripheral circuit region PERI1 may be disposed between the contact regions CTR spaced apart in the third direction D3. The second peripheral circuit region PERI2 may be disposed in the cell region CELL. For example, the second peripheral circuit region PERI2 may be disposed between bit lines BL spaced apart in the third direction D3.

In FIG. 13, the semiconductor memory device described with reference to FIGS. 3 to 11 may be applicable for FIG. 13, except that there are changes in the arrangement of the cell region CELL, the first peripheral circuit region PERI1, and the second peripheral circuit region PERI2.

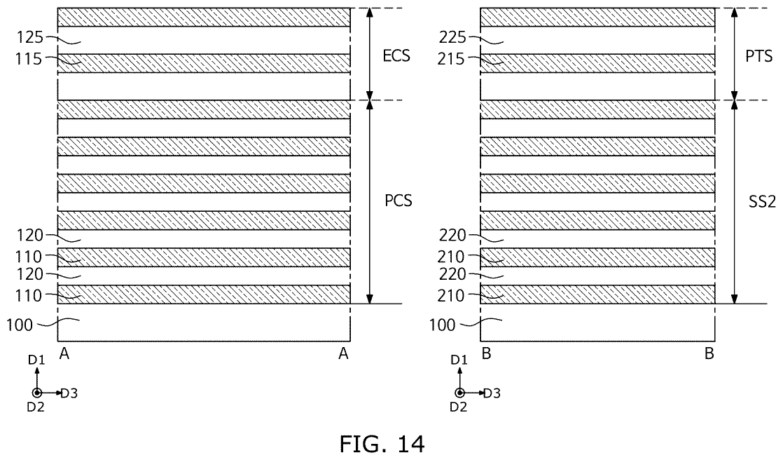

FIGS. 14 to 17 are diagrams showing an intermediate stage of process, which are provided to explain a method for manufacturing a semiconductor memory device according to some example embodiments of the inventive concepts. For reference, FIGS. 14 to 17 may be diagrams corresponding to cross-sectional views taken along line A-A and line B-B of FIG. 3.

Referring to FIGS. 3 and 14, a pre-cell structure PCS, a dummy cell structure ECS, the second stack structure SS2, and a pre-transistor structure PTS may be formed on the upper surface of the substrate 100.

Specifically, the pre-cell structure PCS and the dummy structure ECS may be formed on the cell region CELL of the substrate 100. The pre-cell structure PCS may include a plurality of first cell semiconductor layers 110 and a plurality of second cell semiconductor layers 120 which are alternately stacked on each other. The plurality of first cell semiconductor layers 110 and the plurality of second cell semiconductor layers 120 may be alternately and repeatedly stacked in the first direction D1.

The dummy cell structure ECS may be formed on the pre-cell structure PCS. The dummy cell structure ECS may include a plurality of third cell semiconductor layers 115 and a plurality of fourth cell semiconductor layers 125 which are alternately stacked on each other. The plurality of third cell semiconductor layers 115 and the plurality of fourth cell semiconductor layers 125 may be alternately and repeatedly stacked in the first direction D1.

The second stack structure SS2 may be formed on the first peripheral circuit region PERI1 of the substrate 100. The second stack structure SS2 may include the plurality of first semiconductor layers 210 and the plurality of second semiconductor layers 220 which are alternately stacked on each other. The second stack structure SS2 may be formed simultaneously with the pre-cell structure PCS. The first cell semiconductor layer 110 and the first semiconductor layer 210 may include the same material. The second cell semiconductor layer 120 and the second semiconductor layer 220 may include the same material.

The pre-transistor structure PTS may be formed on the second stack structure SS2. The pre-transistor structure PTS may include a plurality of third semiconductor layers 215 and a plurality of fourth semiconductor layers 225 which are alternately stacked on each other. The pre-transistor structure PTS may be formed simultaneously as the dummy cell structure ECS. The third cell semiconductor layer 115 may include the same material as the third semiconductor layer 215. The fourth cell semiconductor layer 125 may include the same material as the fourth semiconductor layer 225.

Hereinafter, the thickness of each layer may refer to a thickness in the first direction D1. Although the thickness of the third semiconductor layer 215 is illustrated to be the same as the thickness of the first semiconductor layer 210, example embodiments are not limited thereto. The thickness of the third semiconductor layer 215 may be greater or less than the thickness of the first semiconductor layer 210.

The thickness of the fourth semiconductor layer 225 may be greater than the thickness of the second semiconductor layer 220. The thickness of the fourth semiconductor layer 225 may be greater than the thickness of the second cell semiconductor layer 120.

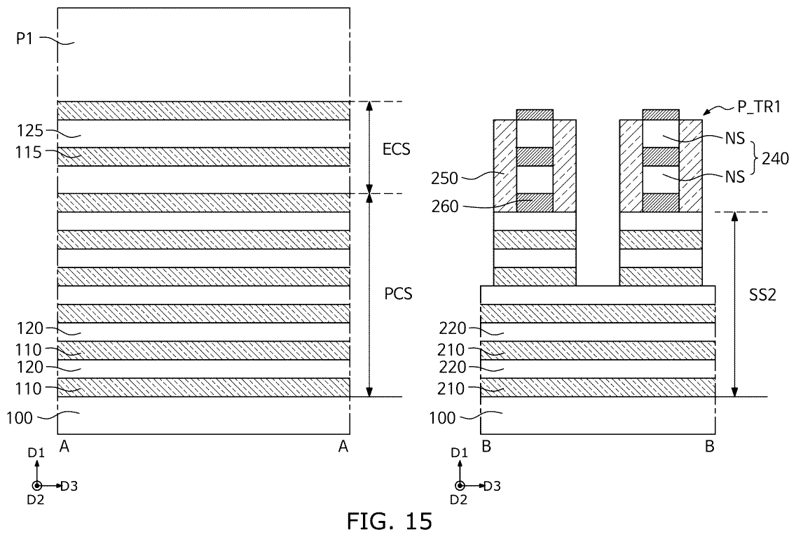

Referring to FIGS. 14 and 15, a first passivation film P1 may be formed on the dummy cell structure ECS, and the first peripheral transistor P_TR1 may be formed on the second stack structure SS2.

Specifically, the first passivation film P1 may be formed on an upper surface of the dummy cell structure ECS. The first passivation film P1 may cover the dummy cell structure ECS. The first passivation film P1 may protect the dummy cell structure ECS and the pre-cell structure PCS during the formation of the first peripheral transistor P_TR1.

A portion of the pre-transistor structure PTS may be removed, and the first peripheral transistor P_TR1 may be formed. For example, a portion of the fourth semiconductor layer 225 of the pre-transistor structure PTS may be removed, thereby forming the peripheral channel pattern 240 including the plurality of sheet patterns NS.

In some example embodiments, the upper portion of the second stack structure SS2 may be used for forming the first peripheral transistor P_TR1. For example, the first semiconductor layer 210 disposed at the uppermost end of the second stack structure SS2 may be used for forming the peripheral gate electrode 260 of the first peripheral transistor P_TR1.

When the first peripheral transistor P_TR1 is formed, a portion of the second stack structure SS2 may be removed, thereby forming a trench. For example, the trench may be formed between adjacent first peripheral transistors P_TR1 in the third direction D3. A field insulating film may be formed on the trench. The field insulating film may separate the adjacent first peripheral transistors P_TR1 in the third direction D3.

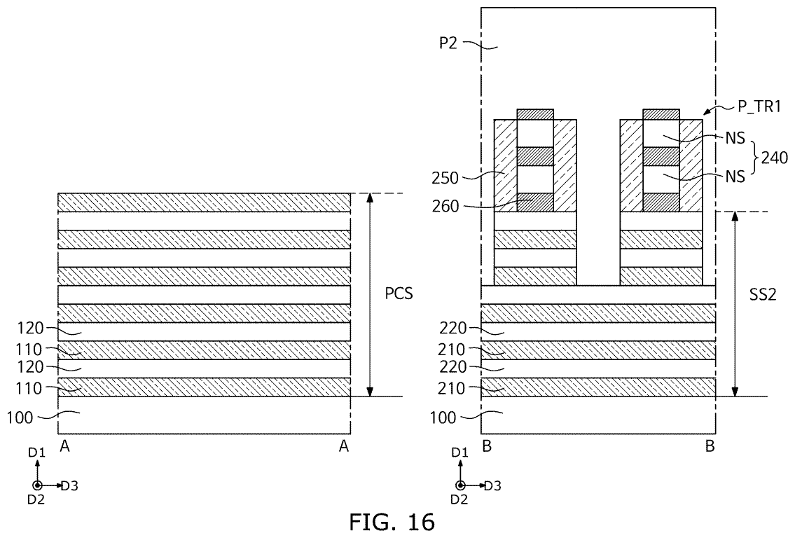

Referring to FIGS. 15 and 16, a second passivation film P2 may be formed on the first peripheral transistor P_TR1 and the dummy cell structure ECS may be removed.

Specifically, the second passivation film P2 may be formed on the first peripheral transistor P_TR1 and the second stack structure SS2. The second passivation film P2 may cover the first peripheral transistor P_TR1 and the second stack structure SS2. The second passivation film P2 may protect the first peripheral transistor P_TR1 and the second stack structure SS2.

The first passivation film P1 and the dummy cell structure ECS may be removed, and the pre-cell structure PCS may be exposed.

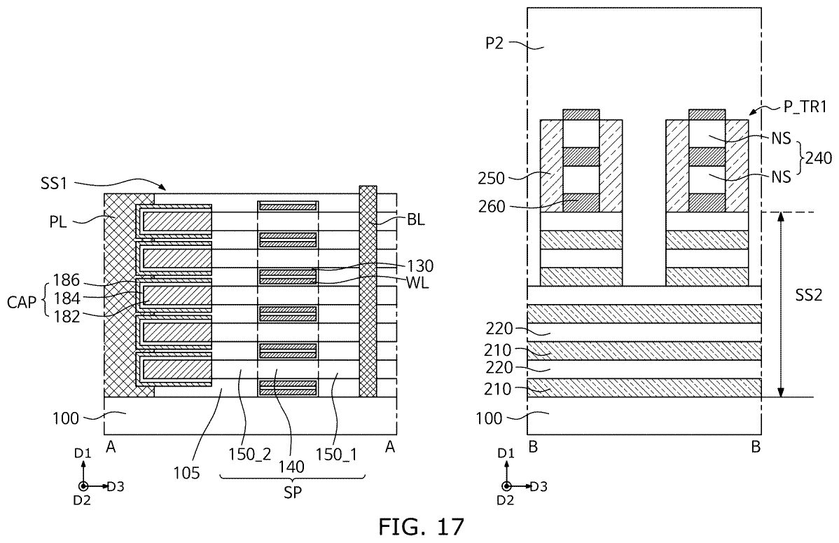

Referring to FIGS. 16 and 17, a portion of the pre-cell structure PCS may be removed, and the first stack structure SS1, the capacitor structure CAP, the plate electrode PL, etc. may be formed. For example, the first cell semiconductor layer 110 may be replaced with an insulating material and the cell insulating film 105 may be formed. A portion of the second cell semiconductor layer 120 may be removed to form the cell channel pattern 140. The description of the first stack structure SS1 may be the same as that described above with reference to FIGS. 3 and 4.

Referring to FIGS. 17 and 7, the first to third contact vias 310, 320, and 330 and the upper wiring structure UWST may be formed on the first peripheral transistor P_TR1 and the first stack structure SS1.

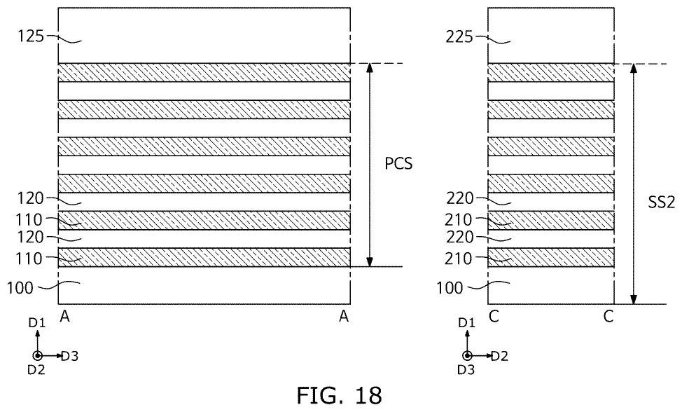

FIGS. 18 to 20 are diagrams showing an intermediate stage of process, which are provided to explain a method for manufacturing a semiconductor memory device according to some example embodiments of the inventive concepts. For reference, FIGS. 18 to 20 may be diagrams corresponding to cross-sectional views taken along line A-A and line C-C of FIG. 9. For convenience of description, different configurations from those described in FIGS. 14 to 17 will be mainly described.

Referring to FIG. 18, the pre-cell structure PCS, the fourth cell semiconductor layer 125, the second stack structure SS2, and the fourth semiconductor layer 225 may be formed on the upper surface of the substrate 100.

The fourth cell semiconductor layer 125 may be formed on the pre-cell structure PCS. The fourth semiconductor layer 225 may be formed on the second stack structure SS2. The fourth cell semiconductor layer 125 and the fourth semiconductor layer 225 may be formed at the same time. The thickness of the fourth semiconductor layer 225 may be greater than the thickness of the second semiconductor layer 220. The thickness of the fourth semiconductor layer 225 may be greater than the thickness of the second cell semiconductor layer 120.

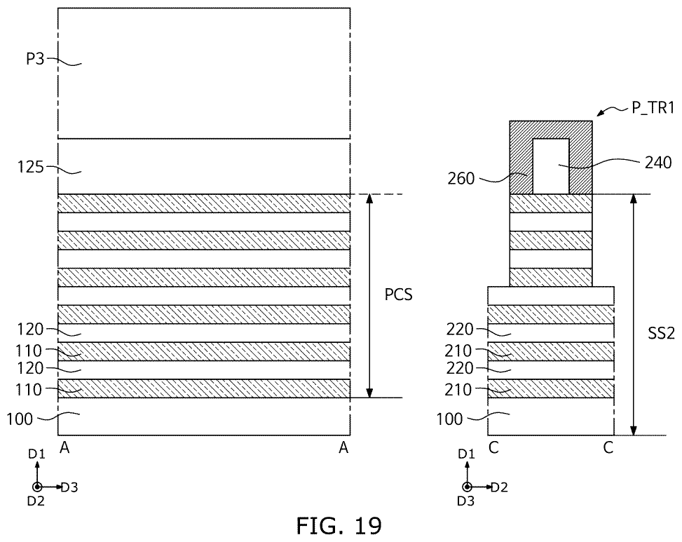

Referring to FIGS. 18 and 19, a third passivation film P3 may be formed on the fourth cell semiconductor layer 125, and the first peripheral transistor P_TR1 may be formed on the second stack structure SS2.

Specifically, the third passivation film P3 may be formed on the upper surface of the fourth cell semiconductor layer 125. The third passivation film P3 may cover the fourth cell semiconductor layer 125. The third passivation film P3 may protect the fourth cell semiconductor layer 125 and the pre-cell structure PCS during the formation of the first peripheral transistor P_TR1.

A portion of the fourth semiconductor layer 225 may be removed, and the first peripheral transistor P_TR1 may be formed. For example, a portion of the fourth semiconductor layer 225 may be removed to form the peripheral channel pattern 240. The peripheral channel pattern 240 may extend in the third direction D3.

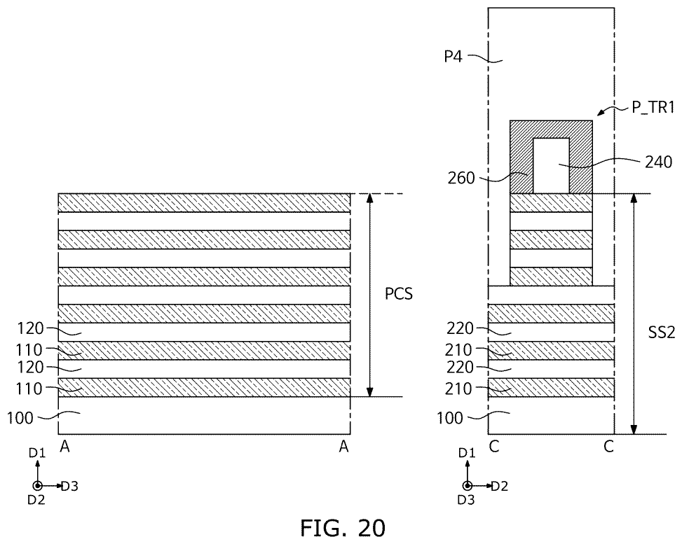

Referring to FIGS. 19 and 20, a fourth passivation film P4 may be formed on the first peripheral transistor P_TR1, and the fourth cell semiconductor layer 125 may be removed.

Specifically, the fourth passivation film P4 may be formed on the first peripheral transistor P_TR1 and the second stack structure SS2. The fourth passivation film P4 may cover the first peripheral transistor P_TR1 and the second stack structure SS2. The fourth passivation film P4 may protect the first peripheral transistor P_TR1 and the second stack structure SS2.

The third passivation film P3 and the fourth cell semiconductor layer 125 may be removed, and the pre-cell structure PCS may be exposed.

Referring to FIGS. 11 and 20, a portion of the pre-cell gate structure PCS may be removed to form the first stack structure SS1, the capacitor structure CAP, the plate electrode PL, etc. The fourth passivation film P4 may be removed, and the first to third contact vias 310, 320, and 330 and the upper wiring structure UWST may be formed on the first peripheral transistor P_TR1 and the first stack structure SS1.

Although certain example embodiments of the inventive concepts have been described with reference to the accompanying drawings, those of ordinary skill in the art to which the inventive concepts pertain will understand that the inventive concepts may be implemented in other specific forms without changing its technical idea or essential features. Therefore, it should be understood that the example embodiments described above are illustrative and non-limiting in all respects.

1. A semiconductor memory device, comprising:
a substrate including a cell region and a peripheral circuit region;
a peripheral transistor on the peripheral circuit region and including a peripheral channel pattern;
a plurality of cell channel patterns stacked on the cell region in a first direction, the first direction being perpendicular to an upper surface of the substrate;
a word line on the plurality of cell channel patterns and the word line extending in a second direction, the second direction being perpendicular to the first direction; and
a bit line connected to each of the plurality of cell channel patterns and the bit line extending in the first direction,
wherein a distance from the upper surface of the substrate to an upper surface of a cell channel pattern at an uppermost portion of the plurality of cell channel patterns is equal to or less than a distance from the upper surface of the substrate to an upper surface of the peripheral channel pattern.

2. The semiconductor memory device according to claim 1, wherein
a thickness of any one of the plurality cell channel patterns in the first direction is same as a thickness of the peripheral channel pattern in the first direction.

3. The semiconductor memory device according to claim 1, wherein
the peripheral transistor further includes a peripheral gate electrode surrounding the peripheral channel pattern, and
the peripheral channel pattern includes a plurality of sheet patterns.

4. The semiconductor memory device according to claim 3, wherein a thickness of any one of the plurality of cell channel patterns in the first direction is same as a thickness of any one of the plurality of sheet patterns in the first direction.

5. The semiconductor memory device according to claim 3, wherein a thickness of any one of the plurality of cell channel patterns in the first direction is different from a thickness of any one of the plurality of sheet patterns in the first direction.

6. The semiconductor memory device according to claim 3, wherein
each of the plurality of cell channel patterns has a first thickness in the first direction,
a thickness of any one of the plurality of sheet patterns in the first direction is greater than the first thickness, and
a thickness of another one of the plurality of sheet patterns is same as the first thickness.

7. The semiconductor memory device according to claim 1, wherein
the peripheral channel pattern has a fin shape extending in a third direction, the third direction crossing each of the first direction and the second direction, and
the peripheral transistor further includes a peripheral gate electrode surrounding the peripheral channel pattern.

8. The semiconductor memory device according to claim 7, wherein
the peripheral channel pattern includes a channel semiconductor layer and a sheet pattern alternately stacked on each other, and
each of the channel semiconductor layer and the sheet pattern includes at least one of silicon or silicon germanium.

9. The semiconductor memory device according to claim 7, wherein
a thickness of the peripheral channel pattern in the first direction is greater than a thickness of any one of the plurality of cell channel patterns in the first direction.

10. The semiconductor memory device according to claim 1, further comprising a stack structure on the peripheral circuit region, wherein the peripheral transistor is on the stack structure.

11. The semiconductor memory device according to claim 10, wherein
the stack structure includes a plurality of first semiconductor layers and a plurality of second semiconductor layers alternately stacked on each other, and
at least some of the plurality of second semiconductor layers and the plurality of cell channel patterns are on a same level.

12. The semiconductor memory device according to claim 1, wherein
the plurality of cell channel patterns extend in a third direction, the third direction being perpendicular to each of the first direction and second direction, and
the semiconductor memory device further includes a plurality of capacitor structures respectively connected to each of the plurality of cell channel patterns.

13. The semiconductor memory device according to claim 1, wherein the peripheral channel pattern and the plurality of cell channel patterns include a same material.

14. A semiconductor memory device, comprising:
a substrate including a cell region and a first peripheral circuit region;
a first peripheral transistor on the first peripheral circuit region and including a peripheral channel pattern;
a plurality of cell channel patterns stacked on the cell region in a first direction, the first direction being perpendicular to an upper surface of the substrate;
a bit line connected to the plurality of cell channel patterns and the bit line extending in the first direction;
an upper wiring structure spaced apart from each of the first peripheral transistor and the plurality of cell channel patterns in the first direction;
a first contact via connected to the upper wiring structure and the bit line and extending in the first direction; and
a second contact via connected to the upper wiring structure and the first peripheral transistor and extending in the first direction,
wherein a length of the first contact via in the first direction is greater than a length of the second contact via in the first direction.

15. The semiconductor memory device according to claim 14, wherein
the first peripheral transistor further includes a peripheral gate electrode on the peripheral channel pattern, and
a thickness of the peripheral channel pattern in the first direction is greater than a thickness of each of the plurality of cell channel patterns in the first direction.

16. The semiconductor memory device according to claim 14, further comprising
a plurality of word lines on the plurality of cell channel patterns,
wherein the plurality of word lines extend in a second direction perpendicular to the first direction and have a stepped structure on a contact region of the substrate.

17. The semiconductor memory device according to claim 16, further comprising
a second peripheral transistor on a second peripheral circuit region and including a peripheral channel pattern, wherein
the first peripheral transistor is spaced apart from the cell region in the second direction, and is electrically connected to the plurality of word lines, and
the second peripheral transistor is spaced apart from the cell region in a third direction and is electrically connected to the bit line, the third direction being perpendicular to each of the first direction and the second direction.

18. The semiconductor memory device according to claim 16, further comprising
a third peripheral transistor on an upper surface of the upper wiring structure, wherein
the third peripheral transistor is electrically connected to the plurality of word lines, and
the first peripheral transistor is electrically connected to the bit line.

19. A semiconductor memory device comprising:
a substrate including a cell region, a contact region, and a peripheral circuit region;
a stack structure on the peripheral circuit region;
a peripheral transistor on the stack structure and including a peripheral channel pattern;
a plurality of cell channel patterns stacked on the cell region in a first direction, the first direction being perpendicular to an upper surface of the substrate;
a word line on the plurality of cell channel patterns and the word line extending in a second direction, the second direction being perpendicular to the first direction;
a bit line connected to one end of each of the plurality of cell channel patterns and the bit line extending in the first direction; and
a plurality of capacitor structures respectively connected to an opposite end of each of the plurality of cell channel patterns,
wherein a distance from the upper surface of the substrate to an upper surface of a cell channel pattern at an uppermost portion of the plurality of cell channel patterns is less than a distance from the upper surface of the substrate to an upper surface of the peripheral channel pattern, and
the word line has a stepped structure on the contact region.

20. The semiconductor memory device according to claim 19, wherein a thickness of the peripheral channel pattern in the first direction is different from a thickness of each of the plurality of cell channel patterns in the first direction.
